(19) United States
(12) Patent Application Publication
(10) Pub. No.: US 2022/0416049 A1
(43) Pub. Date: Dec. 29, 2022

(54) SEMICONDUCTOR STRUCTURE AND FABRICATION METHOD THEREOF

(71) Applicants: CHANGXIN MEMORY TECHNOLOGIES, INC., Hefei (CN); BEIJING SUPERSTRING ACADEMY OF MEMORY TECHNOLOGY, Beijing (CN)

(72) Inventors: Guangsu SHAO, Hefei (CN); Deyuan XIAO, Hefei (CN); Weiping BAI, Hefei (CN); Yunsong QIU, Hefei (CN)

(21) Appl. No.: 17/897,242

(22) Filed: Aug. 29, 2022

(30) Foreign Application Priority Data
Nov. 19, 2021 (CN) 202111397843.6

(51) Int. Cl. H01L 29/423; H01L 29/786; H01L 29/66

(52) U.S. Cl. CPC H01L 29/42392; H01L 29/78696; H01L 29/66545; H01L 29/6681

(57) ABSTRACT

Embodiments disclose a semiconductor structure and a fabrication method thereof. The method includes: providing a substrate; forming a stack structure on a surface of the substrate, where the stack structure includes a first semiconductor material layer and a first sacrificial layer alternately stacked from bottom to top; patterning and etching the stack structure and removing part of the first sacrificial layer to form a horizontal strip-shaped structure; forming a gate-all-around structure, where the gate-all-around structure covers part of a surface of the horizontal strip-shaped structure; and forming a bit line, where the bit line is formed in a same horizontal plane as the horizontal strip-shaped structure and the horizontal strip-shaped structure is segmented by the bit line, and the bit line is connected to a segmentation of the horizontal strip-shaped structure.

### CROSS-REFERENCE TO RELATED APPLICATION

This application claims priority to Chinese Patent Application No. 202111397843.6, titled “SEMICONDUCTOR STRUCTURE AND FABRICATION METHOD THEREOF” and filed to the State Patent Intellectual Property Office on November 19, 2021, the entire contents of which are incorporated herein by reference.

### TECHNICAL FIELD

The present disclosure relates to the field of dynamic random access memory (DRAM) manufacturing technology, and more particularly, to a semiconductor structure and a fabrication method thereof.

### BACKGROUND

With the continuous development of integrated circuit industries, traditional devices with a planar structure have been difficult to meet requirements for circuit design. Therefore, devices with non-planar structures have emerged, including silicon on insulator (SOD, double-gate, multi-gate and nanowire field effect transistors, and the latest three-dimensional gates.

Semiconductor devices with gate-all-around structures have special performances that effectively limit short channel effect. However, as sizes of the semiconductor devices continues to shrink, process difficult of fabricating the gate-all-around structures becomes higher and higher, and product yield is lower.

### SUMMARY

Based on this, it is necessary to provide a semiconductor structure and a fabrication method thereof to solve problems of higher difficulty and lower yield in fabrication processes of a gate-all-around structure.

The present disclosure discloses a method for fabricating a semiconductor structure, including: providing a substrate; forming a stack structure on a surface of the substrate, where the stack structure includes a first semiconductor material layer and a first sacrificial layer alternately stacked from bottom to top; patterning and etching the stack structure and removing part of the first sacrificial layer to form a horizontal strip-shaped structure; forming a gate-all-around structure, where the gate-all-around structure covers part of a surface of the horizontal strip-shaped structure; and forming a bit line, where the bit line is formed in a same horizontal plane as the horizontal strip-shaped structure and the horizontal strip-shaped structure is segmented by the bit line, and the bit line is connected to a segmentation of the horizontal strip-shaped structure.

In the method for fabricating a semiconductor structure, after the stack structure is patterned, the first sacrificial layer in the stack structure is removed to obtain the dangling horizontal strip-shaped structures arranged in parallel. Next, the gate-all-around structure and the bit lines are fabricated on the basis of the horizontal strip-shaped structures. In this way, process steps are simplified, which is beneficial to reduce process difficulty and improve product yield under the condition that sizes continue to shrink.

In one embodiment, the patterning and etching the stack structure and removing part of the first sacrificial layer to form a horizontal strip-shaped structure includes: forming a plurality of shallow trench isolation structures arranged in parallel in the stack structure, where a given one of the plurality of shallow trench isolation structures penetrates through the stack structure and exposes the surface of the substrate; and removing the first sacrificial layer between adjacent two of the plurality of shallow trench isolation structures, and retaining the first semiconductor material layer to obtain the horizontal strip-shaped structure.

In one embodiment, the step of forming a gate-all-around structure comprises: forming a dielectric layer on the surface of the horizontal strip-shaped structure and on a surface of the given shallow trench isolation structure, respectively; filling a second sacrificial layer, the second sacrificial layer filing up the given shallow trench isolation structure and covering the horizontal strip-shaped structure; forming a trench and a connection channel in the second sacrificial layer, the trench being positioned in the given shallow trench isolation structure on two sides of the horizontal strip-shaped structure, and the connection channel being positioned on an upper side and a lower side of the horizontal strip-shaped structure to connect and conduct the trench; and filling a word line material layer in the trench and the connection channel.

In one embodiment, the dielectric layer comprises an oxide layer and/or a high dielectric material layer, where the second sacrificial layer includes a silicon nitride layer, and the word line material layer includes a metal layer or a polysilicon layer.

In one embodiment, after the filling a word line material layer in the trench and the connection channel, the method further includes: forming a first spacer in the given shallow trench isolation structure, where the first spacer separates the word line material layer to obtain the plurality of independent gate-all-around structures.

In one embodiment, the forming a first spacer in the given shallow trench isolation structure includes: forming an isolation void in the given shallow trench isolation structure, where the isolation void separates the word line material layer from the second sacrificial layer in the given shallow trench isolation structure; and filling an isolation material in the isolation void to form the first spacer.

In one embodiment, after forming the first spacer, the method further includes: removing the second sacrificial layer to form a sacrificial gap; and filling the isolation material in the sacrificial gap to form a second spacer.

In one embodiment, the isolation material includes silicon dioxide.

In one embodiment, the step of forming the bit line includes: forming a bit line trench, where an extension direction of the bit line trench is perpendicular to an extension direction of the horizontal strip-shaped structure, and the bit line trench penetrates through the stack structure and exposes the surface of the substrate; and forming the bit line and a bit line spacer alternately stacked in the bit line trench, where the bit line is connected to the horizontal strip-shaped structure.

In one embodiment, the first semiconductor material layer includes a single crystal silicon layer, the first sacrificial layer includes a germanium silicide layer, the bit line includes a metal layer, the bit line spacer includes an oxide layer, and the gate-all-around structure includes a metal layer or a polysilicon layer.

The present disclosure also discloses a semiconductor structure, which includes: a substrate; horizontal strip-shaped structures arranged in parallel and stacked above the substrate, where a surface of the horizontal strip-shaped structure is covered with a dielectric layer; a gate-all-around structure covering part of the surface of the horizontal strip-shaped structure; a bit line, where the bit line is formed in a same horizontal plane as the horizontal strip-shaped structure and the horizontal strip-shaped structure is segmented by the bit line, and the bit line is connected to a segmentation of the horizontal strip-shaped structure.

In one embodiment, the horizontal strip-shaped structures are arranged on a same vertical line at intervals, the gate-all-around structure covers part of a surface of the horizontal strip-shaped structure, and an extension direction of the gate-all-around structure is perpendicular to a surface of the substrate.

In one embodiment, the gate-all-around structure includes a first gate-all-around structure and a second gate-all-around structure, where the first gate-all-around structure and the second gate-all-around structure are positioned at two ends of the horizontal strip-shaped structure, respectively.

In one embodiment, the bit line is positioned between the first gate-all-around structure and the second gate-all-around structure, and an extension direction of the bit line is perpendicular to an extension direction of the horizontal strip-shaped structure.

In one embodiment, a material for forming the horizontal strip-shaped structure includes monocrystalline silicon; a material for forming the dielectric layer includes silicon dioxide and/or a high dielectric material; a material for forming the gate-all-around structure includes metal or polysilicon; and a material for forming the bit line includes metal.

### BRIEF DESCRIPTION OF THE DRAWINGS

FIG. 1 is a flow block diagram of a method for fabricating a semiconductor structure according to an embodiment of the present disclosure;

FIG. 2 is a schematic cross-sectional structural diagram showing the semiconductor structure obtained after a stack structure is formed according to an embodiment of the present disclosure;

FIG. 3a is a top view of the semiconductor structure obtained after a shallow trench isolation structure is formed according to an embodiment of the present disclosure;

FIGS. 3b to 3d are schematic partial cross-sectional structural diagrams taken along directions aa′, bb′ and cc′ in FIG. 3a;

FIG. 4a is a top view of the semiconductor structure obtained after part of a first sacrificial layer is removed according to an embodiment of the present disclosure;

FIG. 4b and FIG. 4c are schematic partial cross-sectional structural diagrams taken along the directions bb′ and cc′ in FIG. 4a;

FIG. 5a is a top view of the semiconductor structure obtained after a gate oxide layer is formed according to an embodiment of the present disclosure;

FIGS. 5b to 5d are schematic partial cross-sectional structural diagrams taken along the directions aa′, bb′ and cc′ in FIG. 5a;

FIG. 6a is a top view of the semiconductor structure obtained after a high dielectric material layer is formed according to an embodiment of the present disclosure;

FIGS. 6b to 6d are schematic partial cross-sectional structural diagrams taken along the directions aa′, bb′ and cc′ in FIG. 6a;

FIG. 7a is a top view of the semiconductor structure obtained after a second sacrificial layer is formed according to an embodiment of the present disclosure;

FIGS. 7b to FIG. 7d are schematic partial cross-sectional structural views taken along the directions aa′, bb′ and cc′ in FIG. 7a;

FIG. 8a is a top view of the semiconductor structure obtained after a trench and a connection channel are formed according to an embodiment of the present disclosure;

FIGS. 8b to 8d are schematic partial cross-sectional structural views taken along the directions aa′, bb′ and cc′ in FIG. 8a;

FIG. 9a is a top view of the semiconductor structure obtained after a word line material layer is formed according to an embodiment of the present disclosure;

FIGS. 9b to 9d are schematic partial cross-sectional structural views taken along the directions aa′, bb′ and cc′ in FIG. 9a;

FIG. 10a is a top view of the semiconductor structure obtained after a first spacer is formed according to an embodiment of the present disclosure;

FIGS. 10b to 10d are schematic partial cross-sectional structural views taken along the directions aa′, bb′ and cc′ in FIG. 10a;

FIG. 11a is a top view of the semiconductor structure obtained after a second spacer is formed according to an embodiment of the present disclosure;

FIG. 11b is a schematic partial cross-sectional structural diagram taken along the direction bb′ in FIG. 11a;

FIG. 12a is a top view of the semiconductor structure obtained after a bit line trench is formed according to an embodiment of the present disclosure;

FIGS. 12b to 12c are schematic partial cross-sectional structural views taken along the directions aa′ and bb′ in FIG. 10a;

FIG. 13a is a top view of the semiconductor structure obtained after a bit line and a bit line spacer are formed according to an embodiment of the present disclosure;

FIGS. 13b to 13d are schematic partial cross-sectional structural views taken along the directions aa′, bb′ and cc′ in FIG. 13a; and

FIG. 14 is a top view of the semiconductor structure obtained after a third spacer is formed according to an embodiment of the present disclosure.

Description of reference numerals in the drawings: 100—substrate; 101—first semiconductor material layer; 102—first sacrificial layer; 103—shallow trench isolation structure; 105—horizontal strip-shaped structure; 1051—first horizontal strip-shaped structure; 1052—second horizontal strip-shaped structure; 1053—third horizontal strip-shaped structure; 106—dielectric layer; 106a—gate oxide layer; 106b—high dielectric material layer; 107—second sacrificial layer; 108- trench, 109—connection channel; 110—word line material layer; 111—first spacer; 112—gate-all-around structure; 1121—first gate-all-around structure; 1122—second gate-all-around structure; 113—second spacer; 114—bit line trench; 115—bit line; 116—bit line spacer; and 117—third spacer.

### DETAILED DESCRIPTION

For ease of understanding the present disclosure, the present disclosure will be described more fully hereinafter with reference to the accompanying drawings. Embodiments of the present disclosure are presented in the accompanying drawings. However, the present disclosure may be embodied in many different forms and should not be limited to the embodiments set forth herein. Rather, these embodiments are provided such that disclosed contents of the present disclosure are understood more thoroughly and completely.

Unless otherwise defined, all technical and scientific terms employed herein have the same meaning as commonly understood by one of ordinary skill in the art to which the present disclosure belongs. The terms employed in the specification of the present disclosure are merely for the purpose of describing some embodiments and are not intended for limiting the present disclosure. As used herein, the term “and/or” includes any and all combinations of one or more of the associated listed items.

When describing positional relationship, unless otherwise specified, when an element such as a layer, film or substrate is referred to as being “on” another film layer, it can be directly on the other film layer or intervening film layer may also be present. Further, when a layer is referred to as being “under” another layer, it can be directly under the other layer, or one or more intervening layers may also be present. It is also to be understood that when a layer is referred to as being “between” two layers, it can be the only one between the two layers, or one or more intervening layers may also be present. In the case of “comprising”, “having”, and “including” as described herein, another component may also be added unless a clearly defined term is used, such as “only”, “consisting of”, etc. Unless mentioned to the contrary, terms in the singular form may include the plural form and cannot be understood as one in number.

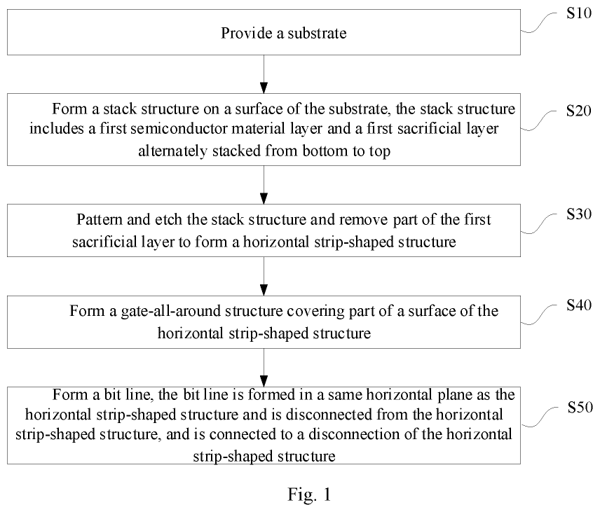

As shown in FIG. 1, one embodiment of the present disclosure discloses a method for fabricating a semiconductor structure, including following steps:

S10: providing a substrate;

S20: forming a stack structure on a surface of the substrate, where the stack structure includes a first semiconductor material layer and a first sacrificial layer alternately stacked from bottom to top;

S30: patterning and etching the stack structure and removing part of the first sacrificial layer to form a horizontal strip-shaped structure;

S40: forming a gate-all-around structure, where the gate-all-around structure covers part of a surface of the horizontal strip-shaped structure; and

S50: forming a bit line, where the bit line is formed in a same horizontal plane as the horizontal strip-shaped structure and the horizontal strip-shaped structure is segmented by the bit line, and the bit line is connected to a segmentation of the horizontal strip-shaped structure.

For example, the substrate in Step S10 may include, but is not limited to, a silicon substrate.

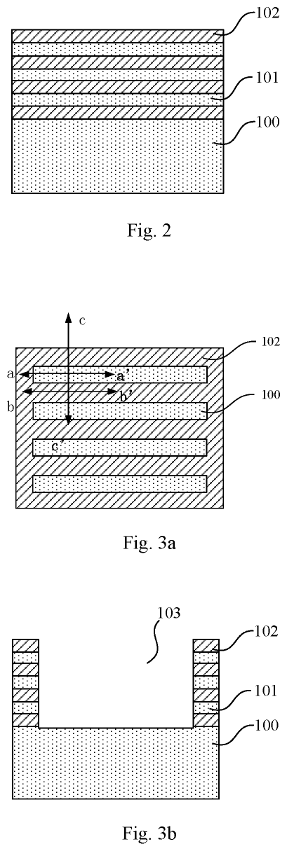

In Step S20, the stack structure formed on the surface of the substrate 100 is shown in FIG. 2. The first semiconductor material layer 101 may include, but is not limited to, a silicon layer, and the first sacrificial layer 102 may include, but is not limited to, a germanium silicide layer. For example, the stack structure may be a superlattice structure. The superlattice structure is formed by alternate growing of thin layers made of two types of different semiconductor materials. Main semiconductor properties of each layer, such as band gap and doping level, may be independently controlled, and a period of multilayer films may also be manually controlled during growth. By fabricating the superlattice structure by means of silicon and germanium silicide, a small-sized semiconductor stack structure may be obtained.

In Step S30, the stack structure is patterned and etched, and part of the first sacrificial layer 102 is removed to form the horizontal strip-shaped structure. In some embodiments, the step of forming a horizontal strip-shaped structure includes following steps.

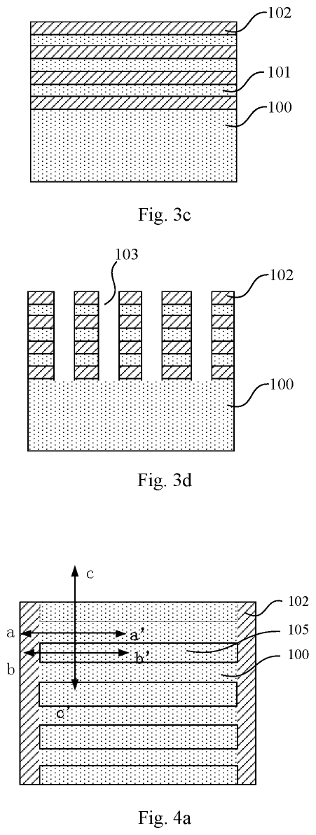

S31: forming a plurality of shallow trench isolation structures 103 arranged in parallel in the stack structure, where a given one of the plurality of shallow trench isolation structures 103 penetrates through the stack structure and exposes the surface of the substrate 100, as shown in FIGS. 3a to 3d.

FIG. 3a is a top view of the semiconductor structure obtained after the shallow trench isolation structure 103 is formed FIG. 3b is a schematic partial cross-sectional structural diagram taken along direction aa′ in FIG. 3a. As can be seen from FIG. 3b, the shallow trench isolation structure 103 penetrates through the stack structure and exposes a part of the surface of the substrate 100. FIG. 3c is a schematic partial cross-sectional structural diagram taken along direction bb′ in FIG. 3a, and FIG. 3d is a schematic partial cross-sectional structural diagram taken along direction cc′ in FIG. 3a.

For example, a patterning process may be performed on the stack structure to form the shallow trench isolation structure 103. For example, the patterning process may include; forming a first mask pattern having a first opening, etching the stack structure using the first mask pattern as an etch mask, and removing the first mask pattern. The shallow trench isolation structures 103 extend in the direction aa′, and number of the shallow trench isolation structures 103 may be multiple.

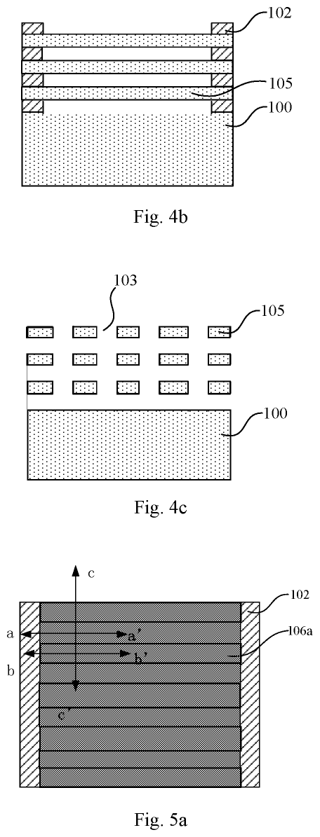

S32: removing the first sacrificial layer 102 between adjacent two shallow trench isolation structures 103, and retaining the first semiconductor material layer 101 to obtain the horizontal strip-shaped structure 105, as shown in FIGS. 4a to 4d.

FIG. 4a is a top view of the semiconductor structure obtained after part of the first sacrificial layer 102 is removed. Schematic partial cross-sectional structural diagrams taken along the directions bb′ and cc′ in FIG. 4a are shown in FIG. 4b and FIG. 4c.

Because there is provided an etching selectivity between the first sacrificial layer 102 (e.g., a germanium silicide layer) and the first semiconductor material layer 101 (e.g., a silicon layer), the first sacrificial layer 102 between adjacent shallow trench isolation structures 103 may be removed by means of wet etching or dry etching, to obtain the horizontal strip-shaped structure 105 in FIG. 4b and FIG. 4c.

In Step S40, a gate-all-around structure is formed, where the gate-all-around structure covers part of the surface of the horizontal strip-shaped structure 105. For example, the step of forming a gate-all-around structure may include following steps.

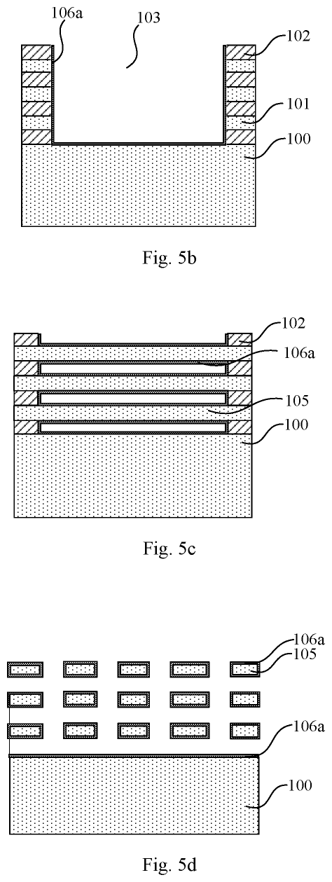

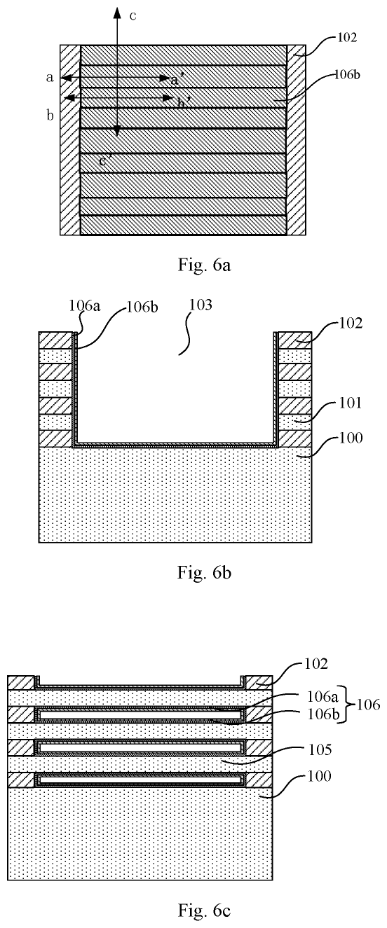

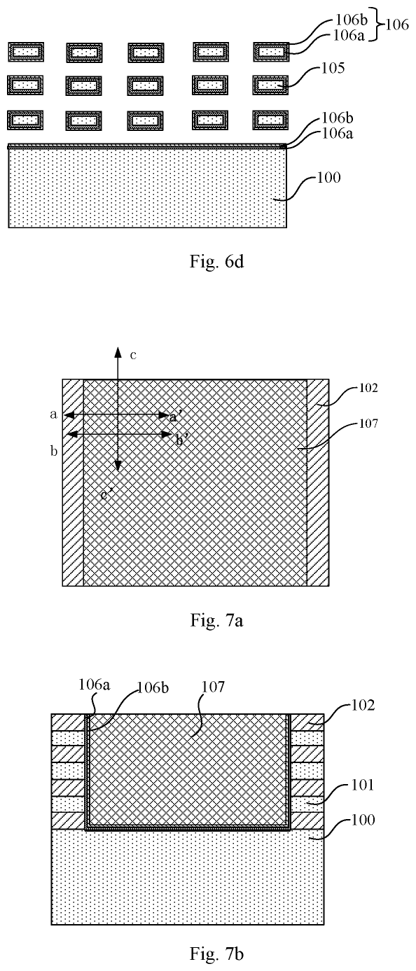

S41: forming a dielectric layer 106 on the surface of the horizontal strip-shaped structure 105 and on a surface of the shallow trench isolation structure 103, respectively, as shown in FIGS. 5a to 6d.

For example, the dielectric layer 106 may include, but is not limited to, a gate oxide layer 106a, which may be, for example, a silicon dioxide layer. FIG. 5a is a top view of the semiconductor structure obtained after the gate oxide layer 106a is formed. FIGS. 5b to 5d are schematic partial cross-sectional structural diagrams taken along the directions aa′, bb′ and cc′ in FIG. 5a. The process of forming the gate oxide layer 106a may be an atomic layer deposition process.

In some embodiments, the dielectric layer 106 may further include a high dielectric material layer 106b (HK material). For example, the high dielectric material layer 106b may be formed on a surface of the gate oxide layer 106a by means of the atomic layer deposition process, as shown in FIGS. 6A to 6d. FIG. 6a is a top view of the semiconductor structure obtained after the high dielectric material layer 106b is formed. FIGS. 6b to 6d are schematic partial cross-sectional structural diagrams taken along the directions aa′, bb′ and cc′ in FIG. 6a. Control ability of a gate can be enhanced by forming the high dielectric material layer 106b on the surface of the gate oxide layer 106a.

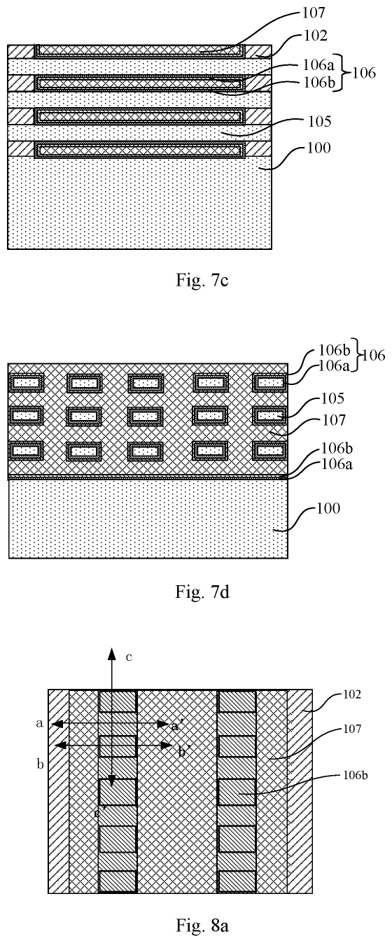

S42: filling a second sacrificial layer 107, where the second sacrificial layer 107 fills up the shallow trench isolation structure 103 and covers the horizontal strip-shaped structure 105, as shown in FIGS. 7A-7d.

FIG. 7a is a top view of the semiconductor structure obtained after the second sacrificial layer 107 is filled. FIGS. 7b to 7d are schematic partial cross-sectional structural views taken along the directions aa′, bb′ and cc′ in FIG. 7a. As shown in FIG. 7a and FIG. 7b, the second sacrificial layer 107 fills up the shallow trench isolation structure 103, and the top surface of the second sacrificial layer 107 is flush with that of the stack structure. As shown in FIG. 7c and FIG. 7d, the second sacrificial layer 107 covers the horizontal strip-shaped structures, and fills up gaps between the horizontal strip-shaped structures arranged on top and bottom.

For example, there is provided etching selectivity between the second sacrificial layer 107 and the gate oxide layer 106a or the high dielectric material layer 106b, to reduce adverse effects on the dielectric layer 106 when etching the second sacrificial layer 107. For example, the second sacrificial layer 107 may include, but is not limited to, a nitride material layer, such as a silicon nitride layer.

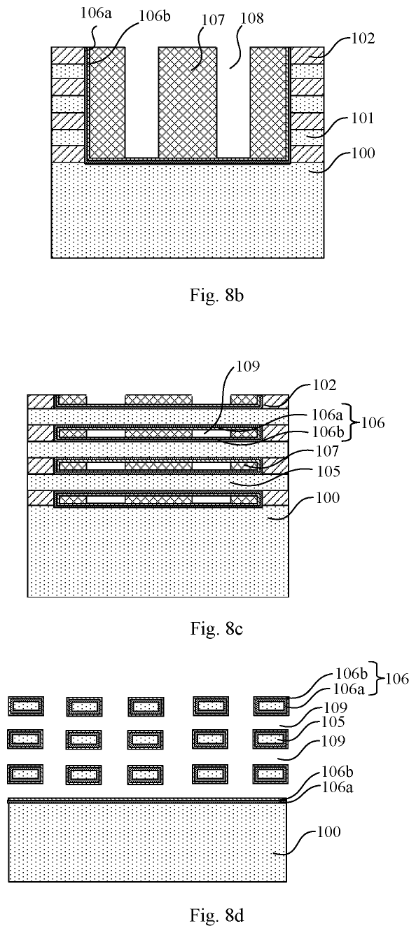

S43: forming a trench 108 and a connection channel 109 in the second sacrificial layer 107, where the trench 108 is positioned in the shallow trench isolation structure 103 on two sides of the horizontal strip-shaped structure 105, and the connection channel 109 is positioned on an upper side and a lower side of the horizontal strip-shaped structure 105 to connect and conduct the trench 108, as shown in FIGS. 8a-8d.

FIG. 8a is a top view of the semiconductor structure obtained after the trench 108 and the connection channel 109 are formed. FIGS. 8b to 8d are schematic partial cross-sectional structural views taken along the directions aa′, bb′ and cc′ in FIG. 8a. As shown in FIG. 8a and FIG. 8b, the trench 108 is positioned inside the shallow trench isolation structure 103 and penetrates through the second sacrificial layer 107 in the shallow trench isolation structure 103 to expose the bottom of the shallow trench isolation structure 103. As shown in FIG. 8c and FIG. 8d, the connection channel 109 is formed between adjacent trenches 108 and is positioned on the upper side and the lower side of the horizontal strip-shaped structure 105.

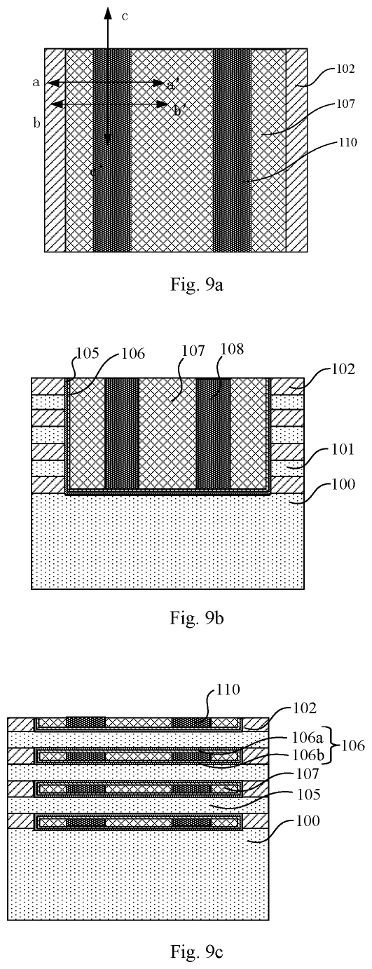

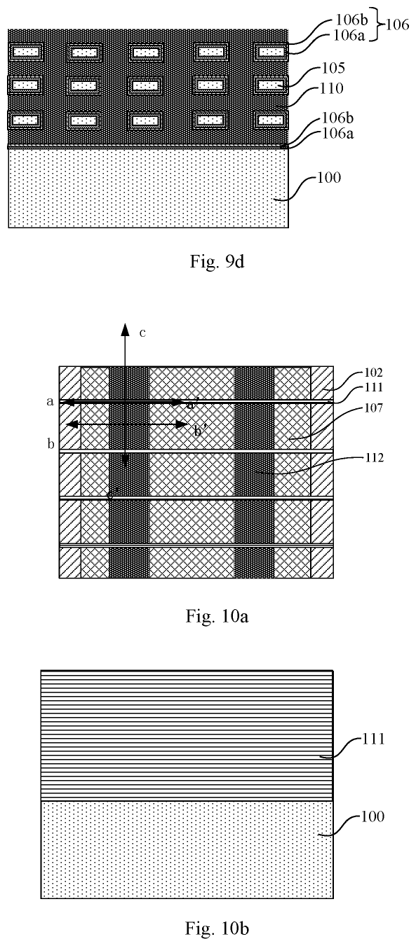

S44: filling a word line material layer 110 in the trench 108 and the connection channel 109, as shown in FIGS. 9a-9d.

FIG. 9a is a top view of the semiconductor structure obtained after the word line material layer 110 is formed. FIGS. 9b to 9d are schematic partial cross-sectional structural views taken along the directions aa′, bb′ and cc′ in FIG. 9a. The word line material layer 110 fills up the trench 108 and the connection channel 109, and a top of the word line material layer 110 is flush with that of the stack structure. For example, the word line material layer 110 may include a metal layer or a doped polysilicon layer, such as a metal titanium layer, a titanium nitride layer, or a metal tungsten layer.

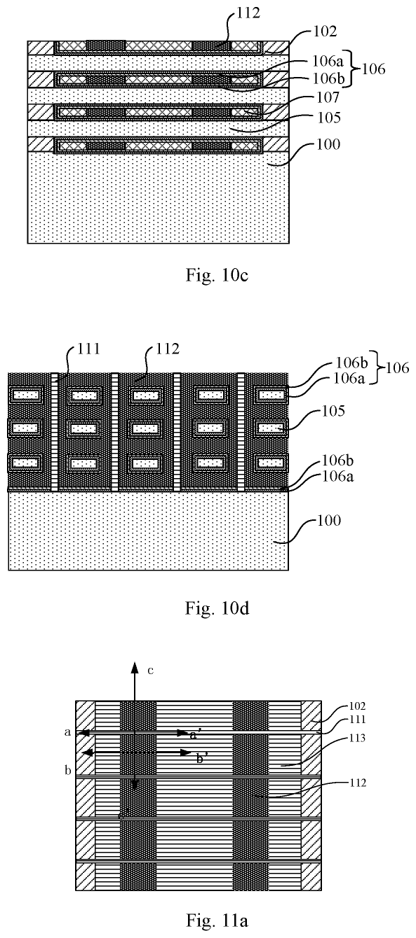

The gate-all-around structures formed through the above steps are connected to each other, and to form a plurality of mutually independent gate-all-around structures, a spacer needs to be formed between adjacent two of the plurality of gate-all-around structures. For example, as shown in FIGS. 10a-10d, after filling the word line material layer 110 in the trench 108 and the connection channel 109, the method further includes: forming a first spacer 111 in the shallow trench isolation structure 103, where the first spacer 111 separates the word line material layer 110 to obtain a plurality of independent gate-all-around structures 112. The step of forming a first spacer 111 includes:

S45: forming an isolation void in the shallow trench isolation structure 103, where the isolation void separates the word line material layer 110 from the second sacrificial layer 107 in the shallow trench isolation structure 103; and

S46: filling an isolation material in the isolation void to form the first spacer 111.

FIG. 10a is a top view of the semiconductor structure obtained after the first spacer 111 is formed according to an embodiment of the present disclosure. FIGS. 10b to 10d are schematic partial cross-sectional structural views taken along the directions aa′, bb′ and cc′ in FIG. 10a. As shown in FIG. 10d, each of the first spacers 111 is positioned in each of the shallow trench isolation structures 103, and word line connection layers positioned in the shallow trench isolation structures 103 are separated to form the plurality of mutually independent gate-all-around structures 112. For example, the first spacer 111 may penetrate through the stack structure along the direction aa′, as shown in FIG. 10a.

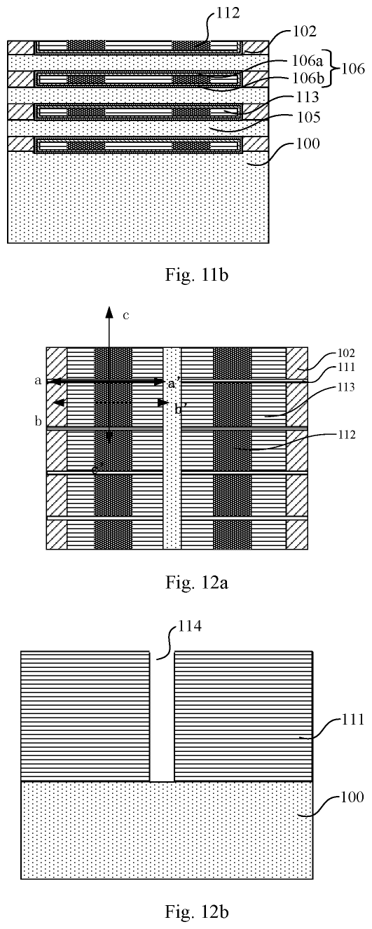

In one embodiment, after forming the first spacer 111, the method further includes: removing the second sacrificial layer 107 to form a sacrificial gap; and filling the sacrificial gap with an isolation material to form the second spacer 113, as shown in FIG. 11a and FIG. 11b. FIG. 11a is a top view of the semiconductor structure obtained after the second spacer 113 is formed. FIG. 11b is a schematic partial cross-sectional structural diagram taken along the direction bb′ in FIG. 11a.

For example, the isolation material may be silicon dioxide, and both the first spacer 111 and the second spacer 113 are silicon dioxide layers.

In Step S50, the step of forming a bit line includes:

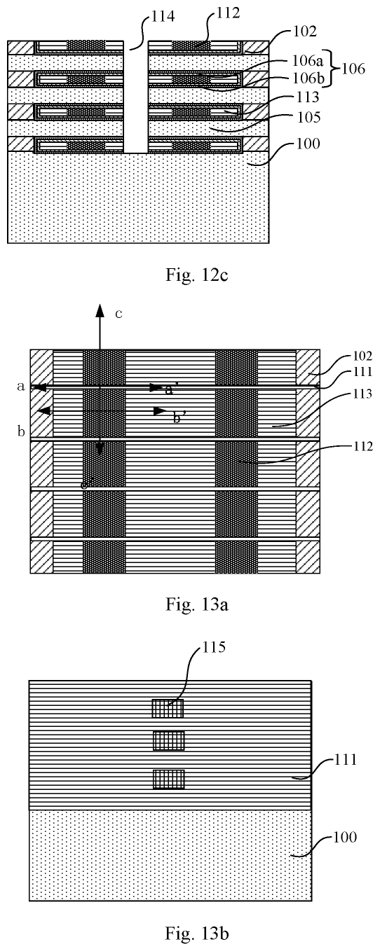

S51: forming a bit line trench 114, where an extension direction of the bit line trench 114 is perpendicular to that of the horizontal strip-shaped structure 105, and the bit line trench 114 penetrates through the stack structure to expose the surface of the substrate 100, as shown in FIGS. 12a to 12c.

FIG. 12a is a top view of the semiconductor structure obtained after the bit line trench 114 is formed according to an embodiment of the present disclosure. FIGS. 12b to 12c are schematic partial cross-sectional structural views taken along the directions aa′ and bb′ in FIG. 12a. As shown in FIG. 12a and FIG. 12c, the bit line trench 114 extends along a direction parallel to the direction cc′, the horizontal strip-shaped structure 105 extends along the direction bb′, and the bit line trench 114 cuts off all the horizontal strip-shaped structures 105 and penetrates through the stack structure, to expose part of the surface of the substrate 100.

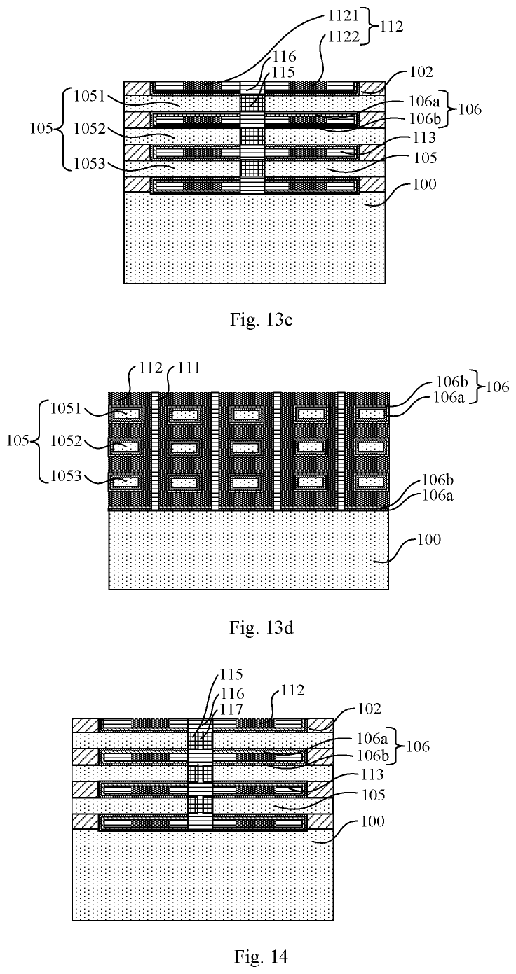

S52: forming the bit line 115 and a bit line spacer alternately stacked in the bit line trench 114, where the bit line is connected to the horizontal strip-shaped structure 105, as shown in FIGS. 13a to 13d.

FIG. 13a is a top view of the semiconductor structure obtained after the bit line 115 and the bit line spacer 116 are formed. FIGS. 13b to 13d are schematic partial cross-sectional structural views taken along the directions aa′, bb′ and cc′ in FIG. 13a.

For example, as shown in FIG. 13c, each of the bit lines 115 and each of the horizontal strip-shaped structures 105 are positioned in the same horizontal plane, and are connected to a segmentation of the horizontal strip-shaped structure 105. The bit line spacer 116 is formed between adjacent bit lines 115. For example, a material for forming the bit line 115 includes metal or doped polysilicon, such as titanium, titanium nitride, or tungsten. A material for forming the bit line spacer 116 may include, but is not limited to, silicon dioxide, silicon nitride, or silicon oxynitride.

In one embodiment, after forming the bit line 115, the method further includes: forming a third spacer 117 in the middle of the bit line 115. For example, as shown in FIG. 14, the third spacer 117 may be formed in the middle of the bit line 115 as shown in FIG. 13c. For example, a material for forming the third spacer 117 may include, but is not limited to, silicon dioxide, silicon nitride, or silicon oxynitride.

In the method for fabricating a semiconductor structure, a superlattice structure is introduced as the stack structure, and the dangling horizontal strip-shaped structures 105 arranged in parallel are fabricated on the basis of the superlattice structure. Next, a gate oxide layer and a word line layer are formed by means of an atomic layer deposition process, and finally vertical word lines and gate-all-around structures are formed. In this way, process challenges brought by size miniature can be reduced, the product yield can be improved, which is beneficial to 3D development of the DRAM structure.

One embodiment of the present disclosure discloses a semiconductor structure, as shown in FIGS. 13a-13d, the semiconductor structure includes: a substrate 100; horizontal strip-shaped structures 105 arranged in parallel and stacked above the substrate 100, where a surface of the horizontal strip-shaped structure is covered with a dielectric layer 106; a gate-all-around structure 112 covering part of the surface of the horizontal strip-shaped structure 105; a bit line 115, where the bit line 115 is formed in the same horizontal plane as the horizontal strip-shaped structure 105 and the horizontal strip-shaped structure is segmented by the bit line 105, and the bit line is connected to a segmentation of the horizontal strip-shaped structure 105.

For example, the substrate 100 may include, but is not limited to, a silicon substrate. As shown in FIG. 13d, the horizontal strip-shaped structures 105 are arranged in an array in space, and are stacked above the substrate 100 in a dangling way. A material for forming the horizontal strip-shaped structure 105 may be silicon, for example. The dielectric layer 106 covering the surface of the horizontal strip-shaped structure 105 may include a gate oxide layer, such as a silicon dioxide layer. In some embodiments, the dielectric layer 106 may further include a high dielectric material layer 106b (HK material).

For example, as can be seen with reference to FIG. 13c and FIG. 13d, the horizontal strip-shaped structures 105 may be arranged on a same vertical line at intervals, the gate-all-around structure 112 covers part of surfaces of the horizontal strip-shaped structures 105 on the same vertical line, and an extension direction of the gate-all-around structure 112 is perpendicular to the surface of the substrate 100. For example, as shown in FIG. 13d, a first horizontal strip-shaped structure 1051, a second horizontal strip-shaped structure 1052 and a third horizontal strip-shaped structure 1053 are arranged on the same vertical line at intervals, and the gate-all-around structure 112 extends along a vertical direction, and covers part of the surface of each of the horizontal strip-shaped structures 105, respectively. For example, the gate-all-around structure 112 may be formed of metal or polysilicon, such as titanium, titanium nitride, or tungsten. A material for forming the bit line 115 may be metal, such as titanium, titanium nitride, or tungsten.

In one embodiment, as shown in FIG. 13c, the gate-all-around structure 112 includes a first gate-all-around structure 1121 and a second gate-all-around structure 1122, where the first gate-all-around structure 1121 and the second gate-all-around structure 1122 are positioned at two ends of the horizontal strip-shaped structure 105, respectively.

In one embodiment, as shown in FIG. 13c, the bit line 115 is positioned between the first gate-all-around structure 1121 and the second gate-all-around structure 1122, and an extension direction of the bit line 115 is perpendicular to that of the horizontal strip-shaped structure 105. For example, as shown in FIG. 13a and FIG. 13c, the extension direction of the bit line 115 is the direction cc′, and the extension direction of the horizontal strip-shaped structure 105 is the direction bb′.

Technical features of the above embodiments may be arbitrarily combined. For simplicity, all possible combinations of the technical features in the above embodiments are not described. However, as long as the combination of these technical features is not contradictory, it shall be deemed to be within the scope recorded in this specification.

The above embodiments merely express a plurality of implementations of the present disclosure, and descriptions thereof are relatively concrete and detailed. However, these embodiments are not thus construed as limiting the patent scope of the present disclosure. It is to be pointed out that for persons of ordinary skill in the art, some modifications and improvements may be made under the premise of not departing from a conception of the present disclosure, which shall be regarded as falling within the scope of protection of the present disclosure. Thus, the scope of protection of the present disclosure shall be merely limited by the appended claims.

What is claimed is:

1. A method for fabricating a semiconductor structure, comprising:
providing a substrate;
forming a stack structure on a surface of the substrate, wherein the stack structure comprises a first semiconductor material layer and a first sacrificial layer alternately stacked from bottom to top;
patterning and etching the stack structure and removing part of the first sacrificial layer to form a horizontal strip-shaped structure;
forming a gate-all-around structure, wherein the gate-all-around structure covers part of a surface of the horizontal strip-shaped structure; and
forming a bit line, wherein the bit line is formed in a same horizontal plane as the horizontal strip-shaped structure and the horizontal strip-shaped structure is segmented by the bit line, and is connected to a segmentation of the horizontal strip-shaped structure.

2. The method for fabricating a semiconductor structure of claim 1, wherein the patterning and etching the stack structure and removing part of the first sacrificial layer to form a horizontal strip-shaped structure comprise:
forming a plurality of shallow trench isolation structures arranged in parallel in the stack structure, wherein a given one of the plurality of shallow trench isolation structures penetrates through the stack structure and exposes the surface of the substrate; and
removing the first sacrificial layer between adjacent two of the plurality of shallow trench isolation structures, and retaining the first semiconductor material layer to obtain the horizontal strip-shaped structure.

3. The method for fabricating a semiconductor structure of claim 2, wherein the forming a gate-all-around structure comprises:
forming a dielectric layer on the surface of the horizontal strip-shaped structure and on a surface of the given shallow trench isolation structure, respectively;
filling a second sacrificial layer, wherein the second sacrificial layer fills up the given shallow trench isolation structure and covers the horizontal strip-shaped structure;
forming a trench and a connection channel in the second sacrificial layer, wherein the trench is positioned in the given shallow trench isolation structure on two sides of the horizontal strip-shaped structure, and the connection channel is positioned on an upper side and a lower side of the horizontal strip-shaped structure to connect and conduct the trench; and
filling a word line material layer in the trench and the connection channel.

4. The method for fabricating a semiconductor structure of claim 3, wherein the dielectric layer comprises an oxide layer and/or a high dielectric material layer, the second sacrificial layer comprises a silicon nitride layer, and the word line material layer comprises a metal layer or a polysilicon layer.

5. The method for fabricating a semiconductor structure of claim 3, wherein, after the filling a word line material layer in the trench and the connection channel, the method further comprises:
forming a first spacer in the given shallow trench isolation structure, wherein the first spacer separates the word line material layer to obtain a plurality of independent gate-all-around structures.

6. The method for fabricating a semiconductor structure of claim 5, wherein the forming a first spacer in the given shallow trench isolation structure comprises:
forming an isolation void in the given shallow trench isolation structure, wherein the isolation void separates the word line material layer from the second sacrificial layer in the given shallow trench isolation structure; and
filling an isolation material in the isolation void to form the first spacer.

7. The method for fabricating a semiconductor structure of claim 6, wherein, after forming the first spacer, the method further comprises:
removing the second sacrificial layer to form a sacrificial gap; and
filling the isolation material in the sacrificial gap to form a second spacer.

8. The method for fabricating a semiconductor structure of claim 7, wherein the isolation material comprises silicon dioxide.

9. The method for fabricating a semiconductor structure of claim 1, wherein the forming the bit line comprises:
forming a bit line trench, wherein an extension direction of the bit line trench is perpendicular to an extension direction of the horizontal strip-shaped structure, and the bit line trench penetrates through the stack structure and exposes the surface of the substrate; and
forming the bit line and a bit line spacer alternately stacked in the bit line trench, wherein the bit line is connected to the horizontal strip-shaped structure.

10. The method for fabricating a semiconductor structure according to claim 1, wherein the first semiconductor material layer comprises a single crystal silicon layer, the first sacrificial layer comprises a germanium silicide layer, the bit line comprises a metal layer, the bit line spacer comprises an oxide layer, and the gate-all-around structure comprises a metal layer or a polysilicon layer.

11. A semiconductor structure, comprising:
a substrate; and
horizontal strip-shaped structures arranged in parallel and stacked above the substrate, wherein a surface of the horizontal strip-shaped structure is covered with a dielectric layer;
a gate-all-around structure covering part of the surface of the horizontal strip-shaped structure;
a bit line, wherein the bit line is formed in a same horizontal plane as the horizontal strip-shaped structure and the horizontal strip-shaped structure is segmented by the bit line, and is connected to a segmentation of the horizontal strip-shaped structure.

12. The semiconductor structure of claim 11, wherein the horizontal strip-shaped structures are arranged on a same vertical line at intervals, the gate-all-around structure covers part of a surface of the horizontal strip-shaped structure, and an extension direction of the gate-all-around structure is perpendicular to a surface of the substrate.

13. The semiconductor structure of claim 12, wherein the gate-all-around structure comprises a first gate-all-around structure and a second gate-all-around structure, and the first gate-all-around structure and the second gate-all-around structure are positioned at two ends of the horizontal strip-shaped structure, respectively.

14. The semiconductor structure of claim 13, wherein the bit line is positioned between the first gate-all-around structure and the second gate-all-around structure, and an extension direction of the bit line is perpendicular to an extension direction of the horizontal strip-shaped structure.

15. The semiconductor structure according to claim 11, wherein a material for forming the horizontal strip-shaped structure comprises silicon; a material for forming the dielectric layer comprises silicon dioxide and/or a high dielectric material; a material for forming the gate-all-around structure comprises metal or polysilicon; and a material for forming the bit line comprises metal.
